(19) United States
(12) Patent Application Publication
(10) Pub. No.: US 2012/0228577 A1
(43) Pub. Date: Sep. 13, 2012

(54) PHASE CHANGE MEMORY DEVICE AND METHOD OF MANUFACTURING THE SAME

(76) Inventors: Kyusul PARK, Suwon-si (KR); JaeHee OH, Seongnam-si (KR); Heung Jin JOO, Suwon-si (KR)

(21) Appl. No.: 13/416,553

(22) Filed: Mar. 9, 2012

(30) Foreign Application Priority Data
Mar. 11, 2011 (KR) 10-2011-0022107

(51) Int. Cl. H01L 45/00

(52) U.S. Cl. 257/4; 257/E45.002

(57) ABSTRACT

A phase change memory device includes a mold oxide layer on a substrate, a lower electrode on the mold oxide layer and connected to the substrate, a blocking structure covering a part of the lower electrode and including an etch-stop layer and a blocking structure insulating layer, and a phase change layer covering a remaining part of the lower electrode not covered by the blocking structure, The etch-stop layer includes a material having a higher etching selectivity than that of the lower electrode.

Korean Patent Application No. 10-2011-0022107, filed on Mar. 11, 2011, in the Korean Intellectual Property Office, and entitled: “Phase Change Memory Device and Method of Manufacturing the Same,” is incorporated by reference herein in its entirety.

### BACKGROUND

Embodiments herein relate to a phase change memory device and method of manufacturing the same.

A phase change memory device may store data using a resistance difference in accordance with a phase transition of a chalcogenide compound constituting a phase change layer. For example, a phase change layer may have different resistance values in an amorphous state and a crystalline state. A phase change layer may be phase-changed depending on a heating temperature of a lower electrode. The lower electrode may include a metal layer having a high resistivity.

### SUMMARY

According to an embodiment, there is provided a phase change memory device including a mold oxide layer on a substrate, a lower electrode on the mold oxide layer and connected to the substrate, a blocking structure covering a part of the lower electrode and including an etch-stop layer and a blocking structure insulating layer, and a phase change layer covering a remaining part of the lower electrode not covered by the blocking structure. The etch-stop layer includes a material having a higher etching selectivity than a material of the lower electrode. The etch-stop layer may include a metal oxide; the metal oxide may include an aluminum oxide; the lower electrode may include a metal nitride layer; and the metal nitride layer may include a titanium nitride.

According to an embodiment, there is provided a method of manufacturing a phase change memory device, the method including forming a mold oxide layer having a contact hole exposing a substrate, forming a lower electrode and a gap-fill insulating layer in the contact hole, forming a blocking structure including an etch-stop layer and a blocking structure insulating layer covering a part of the lower electrode and the gap-fill insulating layer, and forming a phase change layer on a remaining part of the lower electrode and the gap-fill insulating layer not covered by the blocking structure.

The forming of the etch-stop layer includes depositing an etch-stop material on the mold oxide layer, gap-fill insulating layer and lower electrode and etching the etch-stop material by a reaction gas having a higher etching selectivity for the etch-stop layer in comparison to the lower electrode. The etch-stop material may include a metal oxide; the metal oxide may include an aluminum oxide; and the reaction gas may include at least one of hydrogen fluoride and a fluorocarbon. The method may further include forming a diode in the contact hole under the lower electrode.

The forming of the lower electrode may include forming a metal silicide layer on the diode, and forming a resistance metal layer on a sidewall of the contact hole, the metal silicide layer and the mold oxide. The method may further include forming a diffusion prevention layer on a sidewall of the contact hole after forming the metal silicide layer. The method may further include forming a filler insulating layer of silicon nitride on the resistance metal layer and filling the contact hole.

The forming of the lower electrode may further include evenly removing the filler insulating layer and the resistance metal layer from the mold insulating layer.

The resistance metal layer may include a metal nitride.

According to an embodiment, there is provided a phase change memory device including a mold oxide layer on a substrate, a lower electrode in a gap of the mold oxide layer and connected to the substrate, an upper surface of the mold oxide layer being aligned with an upper surface of the lower electrode, a phase change layer on the upper surface of the lower electrode and a portion of upper surface of the mold oxide layer adjacent to the lower electrode, a blocking structure between a portion of the phase change layer and a portion of the lower electrode, the blocking structure reducing a contact area between the phase change layer and the lower electrode, and the blocking structure including an etch-stop layer and a blocking structure insulating layer. The patterned etch-stop layer includes a material having a higher etching selectivity than a material of the lower electrode.

The etch-stop layer may include a metal oxide and the lower electrode includes a metal nitride.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a circuit diagram relating to a phase change memory device in accordance with some embodiments.

FIG. 2 illustrates a cross sectional view relating to the phase change memory device of FIG. 1.

FIGS. 3A through 3R illustrate cross sectional views relating to a method of manufacturing a phase change memory device in accordance with some embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. In the drawings, the thickness of layers and regions are exaggerated for clarity. It will also be understood that when an element such as a layer, region or substrate is referred to as being “on” or “onto” another element, it may lie directly on the other element or intervening elements or layers may also be present.

Embodiments may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

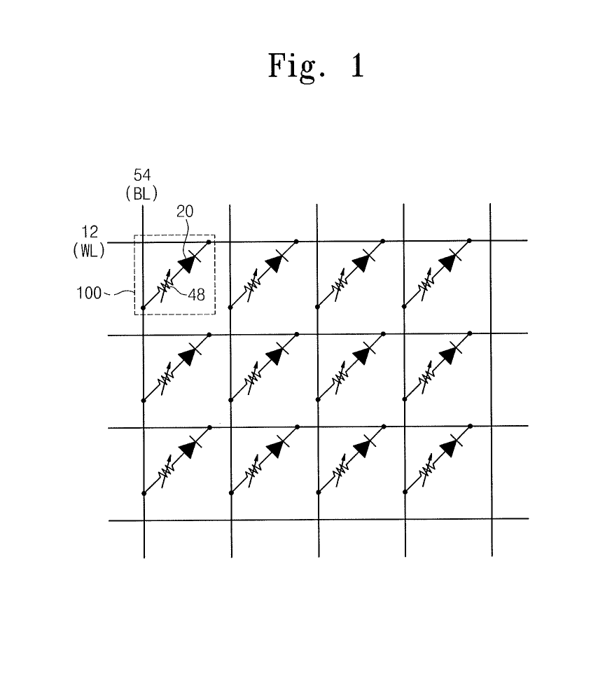

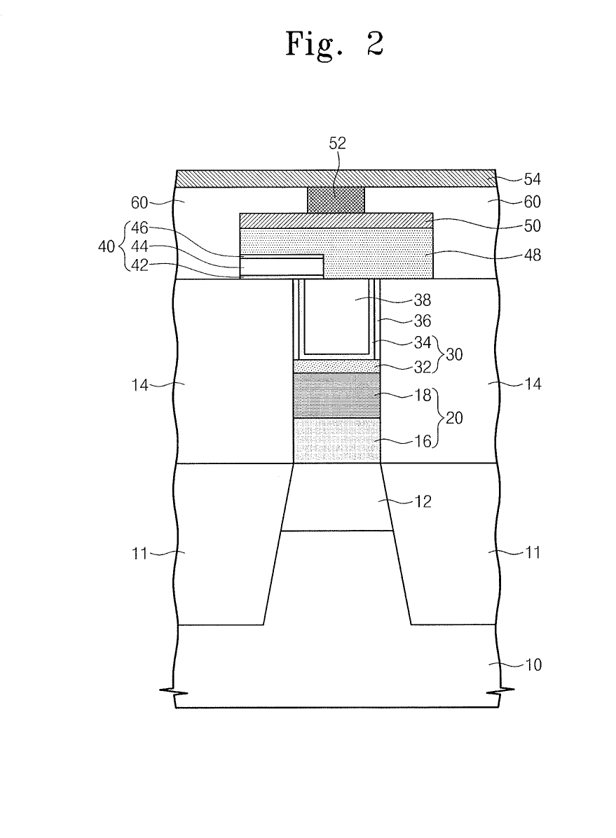

FIG. 1 is a circuit diagram illustrating a phase change memory device in accordance with some embodiments. FIG. 2 is a cross sectional view illustrating the phase change memory device of FIG. 1.

Referring to FIGS. 1 and 2, a phase change memory device in accordance with some embodiments may include a blocking structure 40 including an etch-stop layer 42 of a metal oxide having a higher etching selectivity than a metal nitride of a lower electrode 30. The blocking structure 40 may be disposed at one side between the lower electrode 30 and a phase change layer 48. The blocking structure 40 may modify a contact area between the lower electrode 30 and the phase change layer 48. The blocking structure 40 may include the etch-stop layer 42, a blocking structure insulating layer 44 and a protection layer 46. The lower electrode 30 may include a metal silicide layer 32 formed on a diode 20 and a resistance metal layer 34 formed on the metal silicide layer 32. The resistance metal layer 34 may include a metal having a high resistivity, in order to heat the phase change layer 48 of a memory cell 100 selected by a bit line 54 and a word line 12 to a phase transition temperature. The resistance metal layer 34 may include a metal nitride. The resistance metal layer 34 may be disposed between a gap-fill insulating layer 38 and a diffusion prevention layer 36 and may be connected to the phase change layer 48.

The bit line 54 and the word line 12 may cross each other. A plurality of memory cells 100 may be arranged in a matrix form by the bit lines 54 and the word lines 12 crossing one another. The memory cells 100 may include the phase change layer 48 and the diode 20 as an active device. The phase change layer 48 may include a chalcogenide compound that may be phase-changed to a crystalline state or an amorphous state depending on a temperature change. The phase change layer 48 may have a variable resistance in that the chalcogenide compound may have different resistance values in an amorphous state and a crystalline state. A state of the phase change layer 48 may be determined by the amount of current being provided through the word line 12. The phase change layer 48 may be disposed between an upper electrode 50 and the lower electrode 30. The upper electrode 50 may be electrically connected to the bit line 54 on an interlayer insulating layer 60. The word electrode 30 may be connected to the word line 12 by the diode 20.

The diode 20 may be disposed between the word line 12 and the lower electrode 30. The diode 20 may include a PN junction structure. For example, the diode 20 may include a first conductive impurity layer 16 doped with a first conductive impurity and a second conductive impurity layer 18 doped with a second conductive impurity. The first conductive impurity may include an n-type donor such as phosphorous or arsenic. The second conductive impurity may include a p-type acceptor such as boron or gallium. The diode 20 may be replaced with an active device such as a MOS transistor or a bipolar transistor. The diode 20 and the lower electrode 30 may be disposed in a trench 13 in a mold insulating layer 14.

The metal silicide layer 32 may be in ohmic-contact with the second conductive impurity layer 18 of the diode 20. The metal silicide layer 32 may include cobalt silicide or nickel silicide. The resistance metal layer 34 may provide heat by a current provided from the word line 12 and the diode 20. The gap-fill insulating layer 38 may be disposed on the resistance metal layer 34 in the trench 13. The gap-fill insulating layer 38 may include a silicon nitride or a silicon oxide. The diffusion prevention layer 36 may surround the resistance metal layer 34 on an inner sidewall of the trench 13. The diffusion prevention layer 36 may include a silicon nitride.

The resistance metal layer 34 may be a heater layer that heats the phase change layer 48. The resistance metal layer 34 may include a metal nitride having resistivity 10 to 100 times as large as resistivity of the metal silicide layer 32. For example, the metal nitride may include a titanium nitride, a tantalum nitride, a zirconium nitride or a tungsten nitride. The resistance metal layer 34 may be disposed in the shape of a cup on the metal silicide layer 32. The diffusion prevention layer 36 may surround the outside of the resistance metal layer 34. The gap-fill insulating layer 38 may fill the cup shape on an inside of the resistance metal layer 34. The diffusion prevention layer 36 and the gap-fill insulating layer 38 may include a silicon nitride.

The blocking structure 40 may be disposed between the resistance metal layer 34 and the phase change layer 48. As described above, the blocking structure 40 may modify a contact area between the resistance metal layer 34 and the phase change layer 48. The term “blocking structure 40” may refer generally to a structure that covers one side of the resistance layer 34 disposed between the diffusion prevention layer 36 and the gap-fill insulating layer 38 and exposes the other side of the resistance metal layer 34 to the phase change layer 48. The resistance metal layer 34, the diffusion prevention layer 36, the gap-fill insulating layer 38 and the mold oxide layer 14 may have aligned top surfaces. The blocking structure insulating layer 40 may include a silicon oxide. The etch-stop layer 42 may include a metal oxide. The metal oxide may include at least one of an aluminum oxide, a titanium oxide, a tantalum oxide, a tungsten oxide, a manganese oxide, a molybdenum oxide, a hafnium oxide and a zirconium oxide. The protection layer 46 may include a silicon nitride.

The phase change memory device in accordance with some embodiments may include the blocking structure 40 including the etch-stop layer 42 of metal oxide having a higher etching selectivity than the metal nitride of the resistance metal layer 34. For example, the etching ratio of the resistance metal layer 34 with respect to the etch-stop layer 42 may be from 1:30 to 1:100.

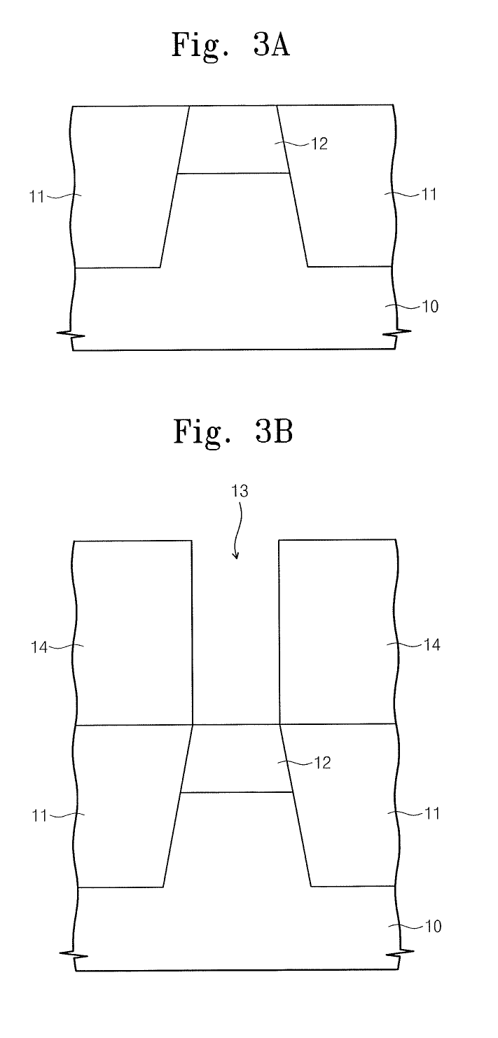

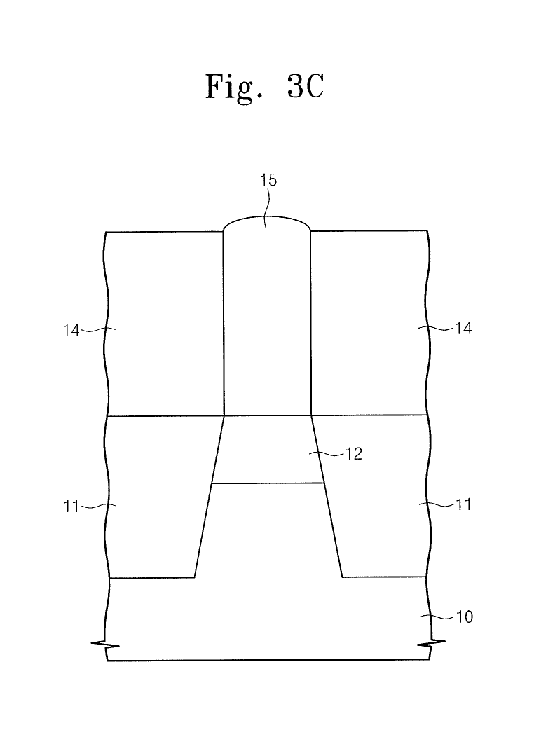

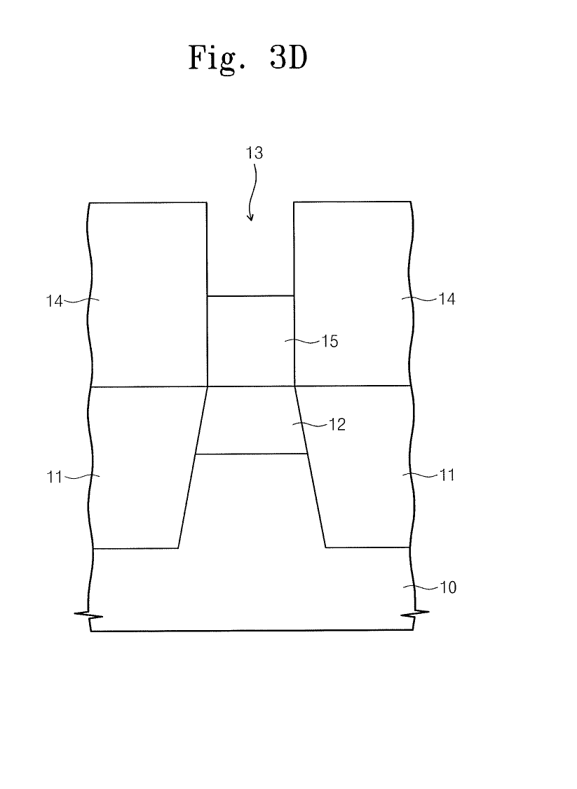

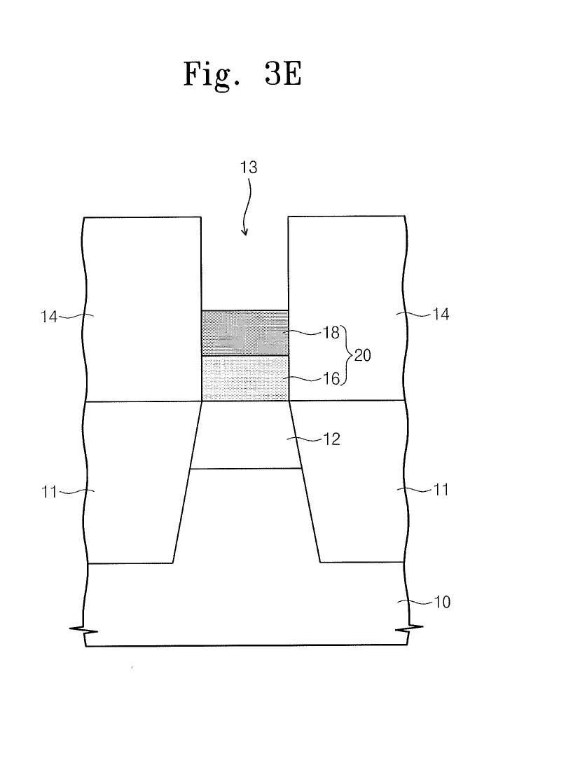

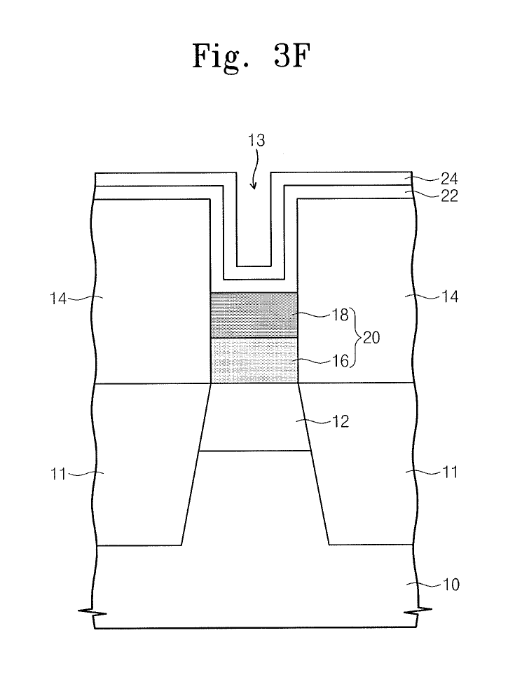

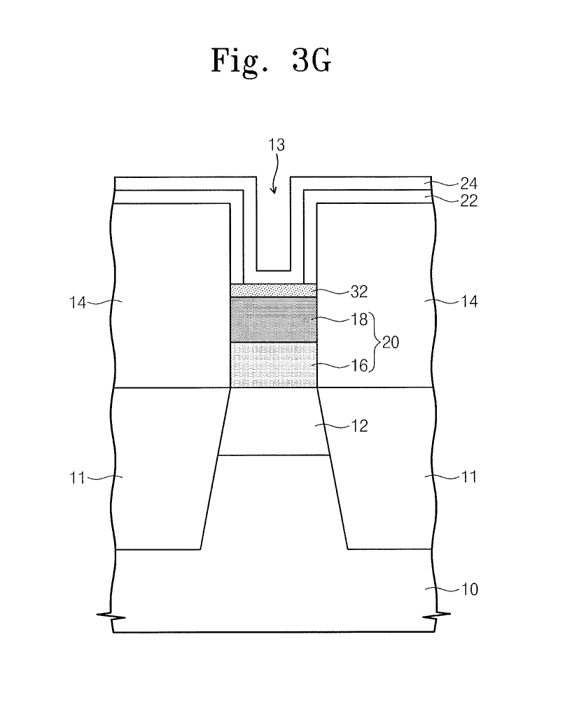

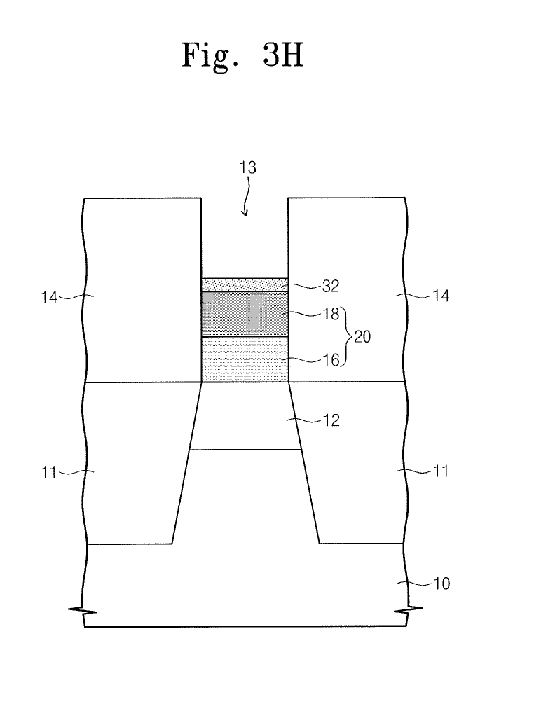

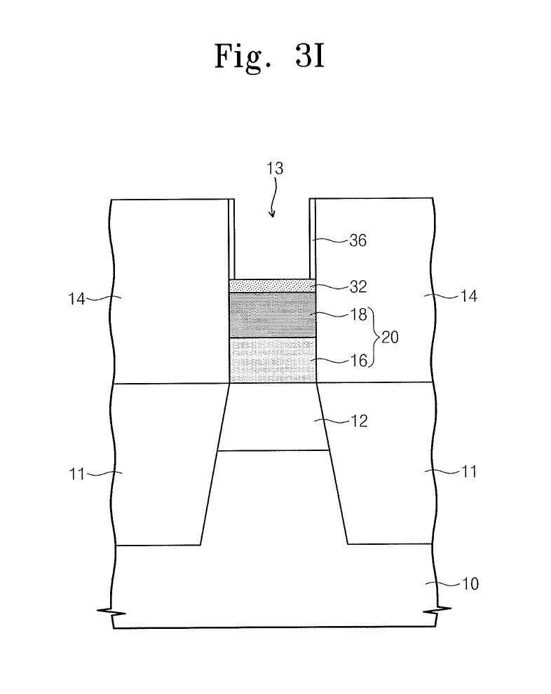

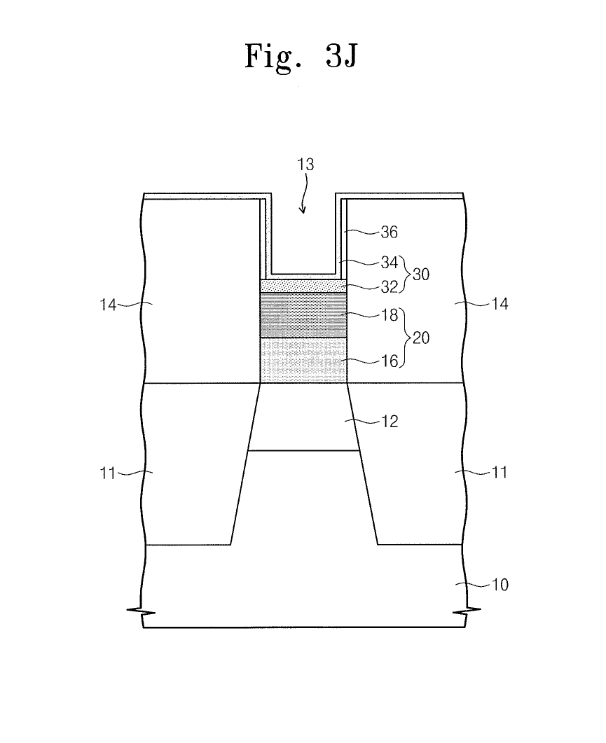

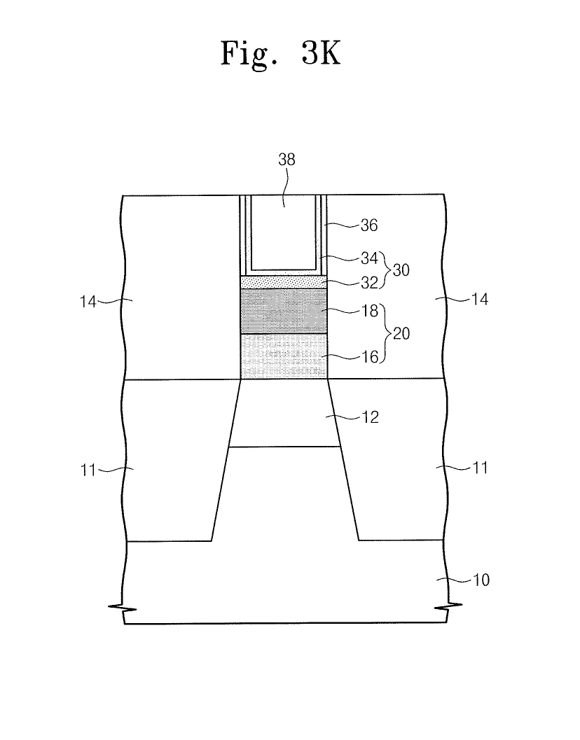

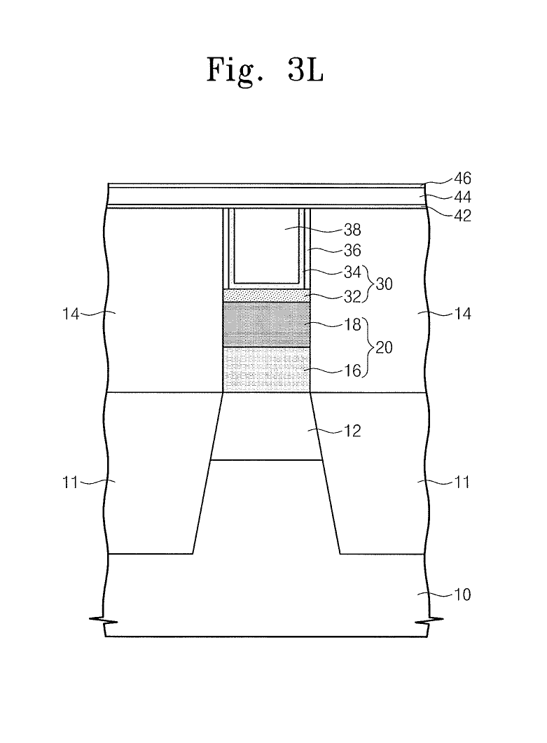

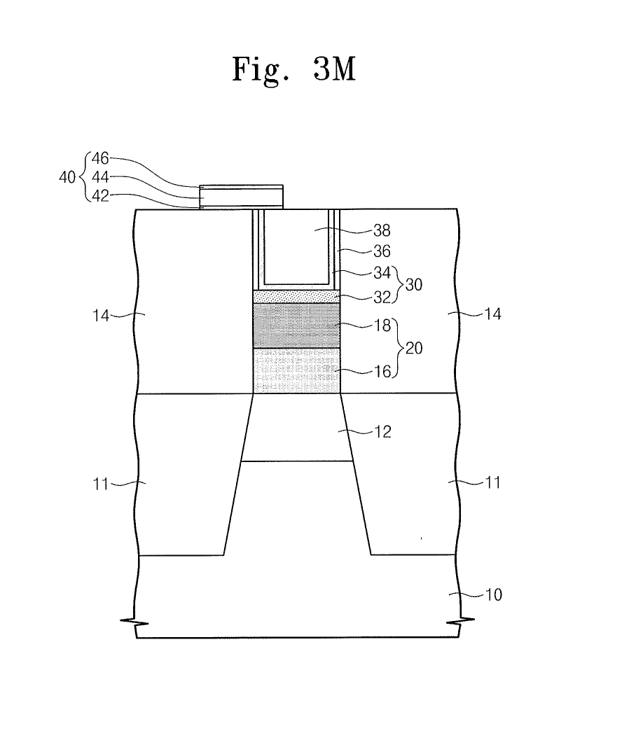

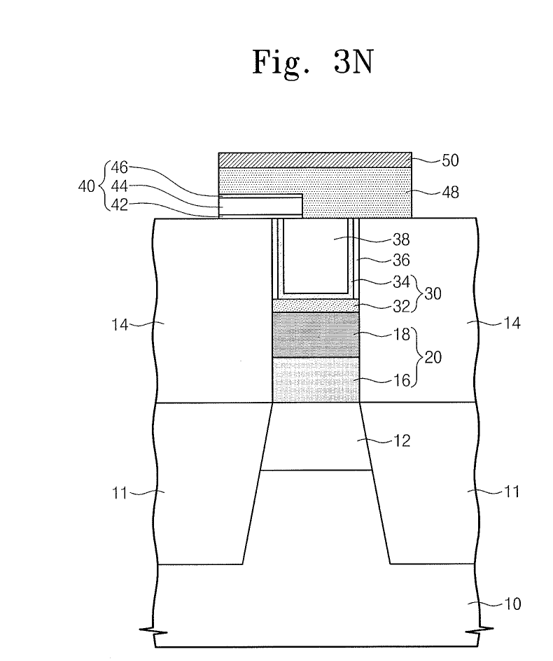

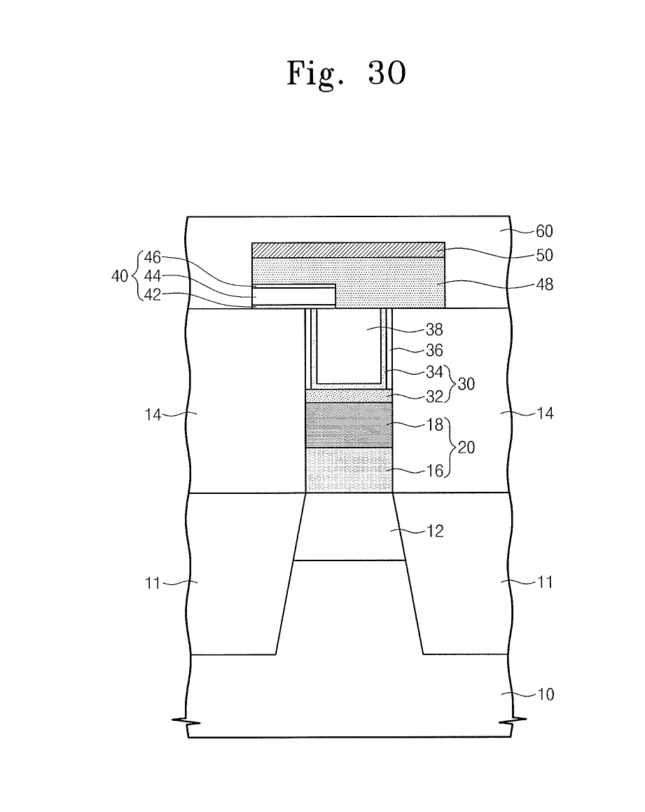

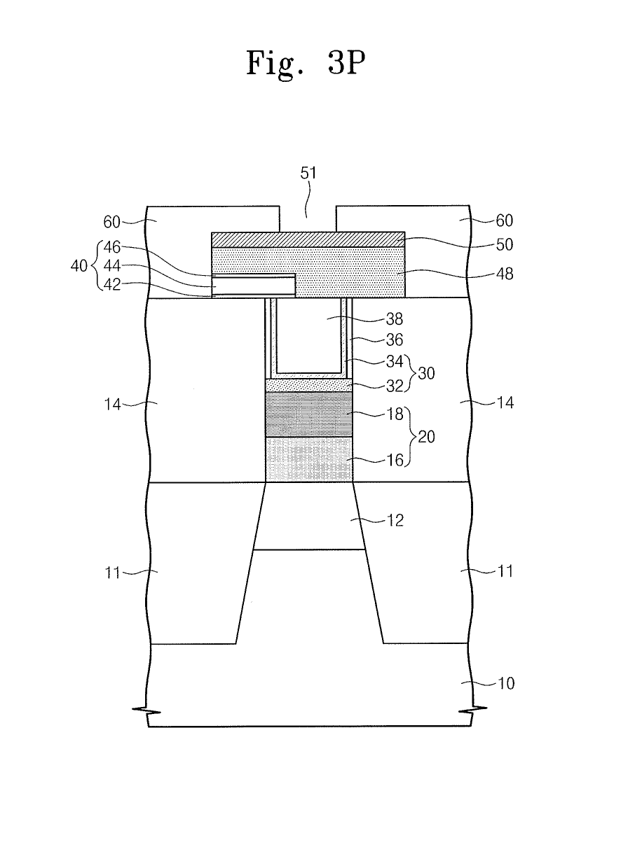

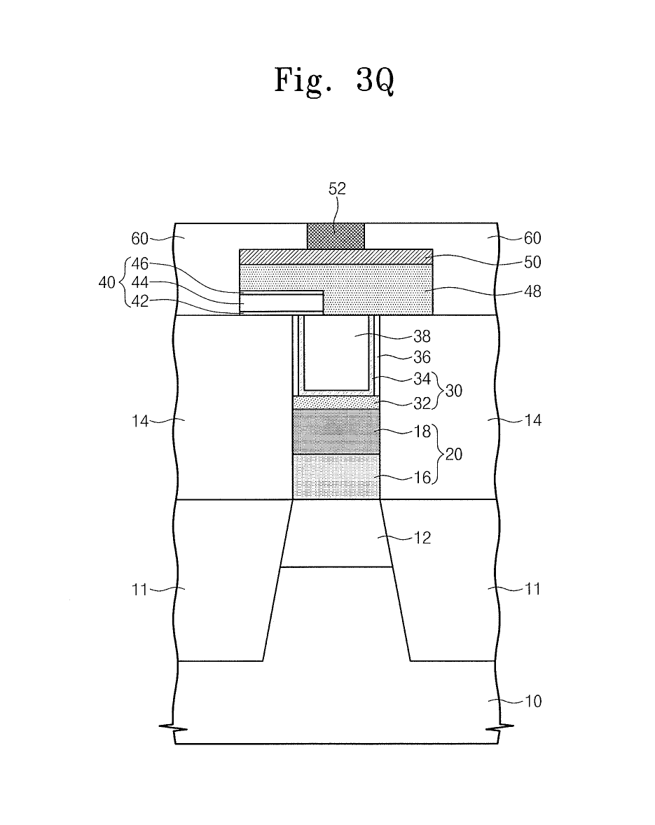

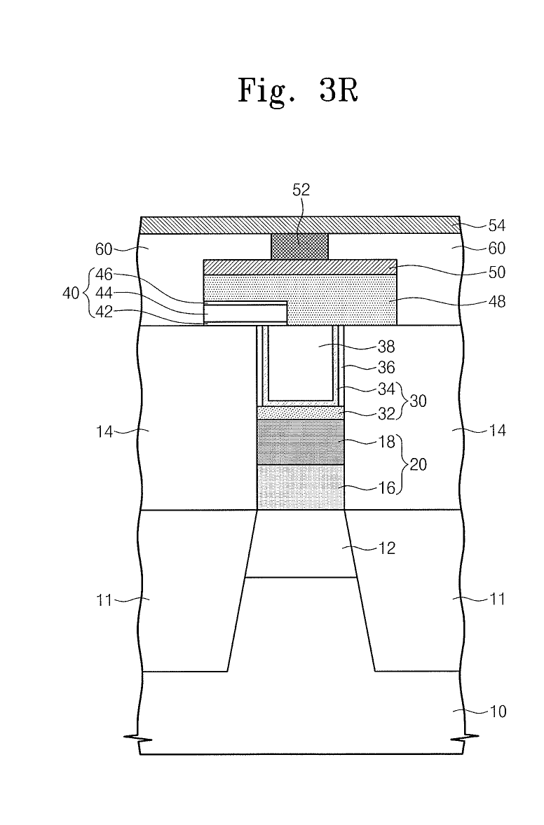

The blocking structure 40 may be in the form of a strip that extends perpendicularly with respect to the cross-sectional view shown in FIGS. 2 and 3A through 3R. For example, the blocking structure 40 may be parallel to the word line 12 shown in FIG. 1 to be included in a plurality of the memory cells 100.

A method of manufacturing the phase change memory device is described as follows.

FIGS. 3A through 3R are cross sectional views illustrating a method of manufacturing a phase change memory device in accordance with some embodiments.

Referring to FIG. 3A, a word line 12 is formed on a substrate 10. The substrate 10 may include crystalline silicon. The word line 12 may include a conductive region resulting from a conductive impurity being ion-implanted into the crystalline silicon. The conductive region may include at least one of a conductive impurity region, a contact pad, a contact plug, a conductive metal pattern and a gate electrode that are formed on the substrate 10. The conductive region may be isolated by a device isolation layer 11. The word line 12 may extend in a specific direction. The device isolation layer 11 may be buried in a groove formed in the substrate 10.

Referring to FIG. 3B, a mold insulating layer 14 having a trench 13 exposing the word line 12 may be formed on the substrate 10. The mold insulating layer 14 may include a silicon oxide in a form of at least one of undoped silicate glass (USG), boron-phosphor silicate glass (BPSG), phosphor silicate glass (PSG), boron silicate glass (GSG), spin on glass (SOG), tetraethylorthosilicate (TEOS), plasma enhanced-tetraethylorthosilicate (PE-TEOS) and a silicon oxide material formed by high density plasma chemical vapor deposition (HDP-CVD). The trench 13 may be formed by a photolithography process. For example, the photolithography process may include a photo process of forming a photoresist pattern exposing the mold insulating layer 14 on the word line 12 and an etching process of removing the exposed mold layer 14 using the photoresist pattern as an etching mask.

Referring to FIG. 3C, a filler layer 15 may be formed in the trench 13. The filler layer 15 may include the same crystalline silicon as the substrate 10 and the word line 12. The filler layer 15 may be formed by a selective epitaxial growth (SEG) method. The selective epitaxial growth (SEG) method may use the crystalline silicon of the word line 12 exposed in the trench 13 as a seed. Thus, the filler layer 15 may include crystalline silicon having a same crystalline direction as the word line 12 and the substrate 10.

Referring to FIG. 3D, the filler layer 15 of the upper portion of the trench 13 is removed. The filler layer 15 may be recessed by an etch-back process. A thickness of filler growth layer remaining on a bottom of the trench 13 may be controlled by a time etching method.

Referring to FIG. 3E, a diode 20 may be formed in the recessed filler layer 15. The diode 20 may include first and second impurity layers 16 and 18 sequentially formed in the trench 13. The first and second impurity layers 16 and 18 may be doped with first and second conductive impurities, respectively. The first and second impurities may be ion-implanted into the recessed filler layer 15 using different energies from each other. For example, the first conductive impurity may include an n-type donor such as phosphorous or arsenic. The second conductive impurity may include a p-type acceptor such as boron or gallium. The word line 12 under the diode 20 may be doped with the first conductive impurity that is the same with that of the first conductive impurity layer 16.

Referring to FIG. 3F, a first metal layer 22 and a second metal layer 24 may be formed on the substrate 10 including the diode 20. The first and second metal layers 22 and 24 may be formed by a chemical vapor deposition method or a sputtering method. The first metal layer 22 may include a silicide reaction metal having a melting point lower than that of the second metal layer 24. For example, the first metal layer 22 may include cobalt or nickel. The second metal layer 24 may include metal that can diffuse well when the first metal layer 22 reacts to silicon. For example, the metal layer 24 may include at least one of titanium, tantalum, tungsten, molybdenum, vanadium, hafnium and zirconium. Although not illustrated in the drawing, a third metal layer may be further formed on the second metal layer 24. The third metal layer may include the same metal as the first metal layer 22. Also, the third metal layer may be a capping layer to improve the morphology of the second metal layer 24. For example, the third metal layer may include a metal nitride such as a titanium nitride.

Referring to FIG. 3G, a metal silicide layer 32 may be formed on the diode 20. The metal silicide layer 32 may be formed by a reaction between the first metal layer 22 and the second conductive impurity layer 18 when performing a first thermal treatment process. The first thermal treatment process may include a rapid thermal treatment process of about 200° C. to about 650° C. For example, the metal silicide layer 32 may include cobalt silicide or nickel silicide. The second metal layer 24 may diffuse into the metal silicide layer 32 when the first thermal treatment process is performed.

Referring to FIG. 3H, a residue of the first metal layer 22 and the second metal layer 24 on the metal silicide layer 32 may be removed. The first and second metal layers 22 and 24 may be removed by a wet etching process or a dry etching process using an etchant or an etching gas having an etching selectivity with respect to the metal silicide layer 32. That is, by an etching process, the first metal layer 22 of a monometallic composition remaining after a metal silicide reaction occurs and the second metal layer 24 may be removed.

Referring to FIG. 31, a diffusion prevention layer 36 may be formed on a sidewall of the trench 13 on the metal silicide layer 32. The diffusion prevention layer 36 may include a silicon nitride. The diffusion prevention layer 36 may be formed by a chemical vapor deposition method and a dry etching method. First, the diffusion prevention layer 36 may be conformally formed on an entire surface of the substrate 10 by a chemical vapor deposition method. After that, by an anisotropic dry etching, the diffusion prevention layer 36 on the mold oxide layer 14 and on a bottom of the trench 13 may be removed such that the diffusion prevention layer 36 on a sidewall of the trench 13 remains.

Referring to FIG. 3J, a resistance metal layer 34 may be formed inside the trench 13 and on the mold oxide layer 14. The resistance metal layer 34 may include a metal nitride and may be formed by a metal-organic chemical vapor deposition (MOCVD) method. For example, the metal nitride may have resistivity 10 to 100 times as large as the resistivity of the metal silicide layer 32. The resistance metal layer 34 may include a titanium nitride, a tantalum nitride, a zirconium nitride or a tungsten nitride. A titanium nitride film may be formed by a metal-organic chemical vapor deposition (MOCVD) method using TDMAT including titanium nitride and BTBAS including silicon nitride as source gases. The metal-organic chemical vapor deposition (MOCVD) method may form a metal nitride layer chemically reacting to a high temperature source gas of about 200° C. or more on the substrate 10 without using a plasma reaction.

Referring to FIG. 3K, a gap-fill insulating layer 38 may be formed on the resistance metal layer 34 and on an entire surface of the substrate 10. The gap-fill insulating layer 38 may be planarized until the mold insulating layer 14 is exposed. The gap-fill insulating layer 38 may fill the trench 13 on the resistance metal layer 34. The gap-fill insulating layer 38 may include a silicon oxide of the same composition as the mold insulating layer 14. The gap-fill insulating layer 38 and the resistance metal layer 34 may be evenly removed on the mold insulating layer 14 by a chemical mechanical polishing (CMP) method. Thus, the resistance metal layer 34 may be exposed to have a round or a polygonal ring shape by the mold insulating layer 14 and the gap-fill insulating layer 38.

Referring to FIG. 3L, an etch-stop layer 42, a blocking structure insulating layer 44 and an protection layer 46 are stacked on an entire surface of the substrate 10. The etch-stop layer 42 may include a metal oxide. The metal oxide may include at least one of an aluminum oxide, a titanium oxide, a tantalum oxide, a tungsten oxide, a manganese oxide, a molybdenum oxide, a hafnium oxide and a zirconium oxide. The protection layer 46 may include a silicon nitride.

Referring to FIG. 3M, the etch-stop layer 42, the blocking structure insulating layer 44 and the protection layer 46 are patterned to form a blocking structure 40 covering a part of the resistance metal layer 34. The etch-stop layer 42, the blocking structure insulating layer 44 and the protection layer 46 may be patterned by a photolithography process. The photolithography process may include a photoresist process of forming a photoresist pattern on the protection layer 46 and an etching process of removing the etch-stop layer 42, the blocking structure insulating layer 44, and the protection layer 46 using the photoresist pattern as a mask. When forming the blocking structure 40 using a dry etching process, the etch-stop layer 42 may have a high etching selectivity with respect to the resistance metal layer 34.

A dry etching process of etching the protection layer 46, the blocking structure insulating layer 44, and the etch-stop layer 42 may be performed using a reaction gas including at least one of hydrogen fluoride (HF) and a fluorocarbon (for example, C₄F₆, C₅F₈). The hydrogen fluoride can remove a silicon oxide and a metal oxide layer at a high speed while the hydrogen fluoride hardly reacts to a nitride layer such as a silicon nitride and a metal nitride layer. A fluorocarbon such as C₄F₆, C₅F₈ can quickly remove an oxide layer such as a silicon oxide and a metal oxide layer while the fluorocarbon cannot substantially remove a nitride layer such as a silicon nitride and a metal nitride layer. Hydrogen fluoride (HF) and fluorocarbon (C₄F₆, C₅F₈) have a superior etching selectivity between an oxide layer and a nitride layer.

Thus, in a method of manufacturing a phase change memory device in accordance with some embodiments, when forming the blocking structure 40, damage to the lower electrode 30 may be minimized because of the use of the etch-stop layer 42 including a metal oxide having a high etching selectivity compared with the metal nitride of the lower electrode 30.

According to an implementation, the protection layer 46, the blocking structure insulating layer 44, and the etch-stop layer 42 may be etched in a two-step process in which the protection layer 46, the blocking structure insulating layer 44 are etched first, with the etch-stop layer 42 protecting the lower electrode 30 from etching, and thereafter, the etch-stop layer 42 may be etched.

Referring to FIG. 3N, a phase change layer 48 and an upper electrode 50 are formed on the resistance metal layer 34. The phase change layer 48 and the upper electrode 50 may be patterned by a photolithography process after the phase change layer 48 and the upper electrode 50 are stacked on the lower electrode 30 by a chemical vapor deposition method and/or a physical vapor deposition method. The phase change layer 48 may include a germanium-antimony-tellurium (GAT) or chalcogenide compound such as germanium-antimony-tellurium (GAT) doped with carbon, nitrogen and/or metal. The upper electrode 50 may include at least one unit metal of titanium, tungsten, aluminum, nickel, zirconium, molybdenum, ruthenium, palladium, hafnium, tantalum, iridium or platinum. Also, the upper electrode 50 may include at least one metal nitride layer of a titanium nitride, a tungsten nitride, an aluminum nitride, a nickel nitride, a zirconium nitride, a molybdenum nitride, a ruthenium nitride, a palladium nitride, a hafnium nitride, a tantalum nitride, an iridium nitride, a platinum nitride, a niobium nitride, a titanium aluminum nitride, a zirconium aluminum nitride, a molybdenum aluminum nitride or a tantalum aluminum nitride.

Referring to FIG. 30, an interlayer insulating layer 60 may be formed on the phase change layer 48 and the upper electrode 50. The interlayer insulating layer 60 may include an oxide material of the same composition as the mold insulating layer 14.

Referring to FIG. 3P, a contact hole 51 may be formed by removing a portion of the interlayer insulating layer 60. The contact hole 51 may be formed by a photolithography process. The photolithography process may include a photo process of forming a photoresist pattern exposing the interlayer insulating layer 60 on the upper electrode 50 and an etching process of removing the interlayer insulating layer 60 using the photoresist pattern as an etching mask.

Referring to FIG. 3Q, a contact plug 52 may be formed in the contact hole 51. The contact plug 52 may include a metal layer such as tungsten, aluminum, copper, tantalum or titanium. The contact plug 52 may be formed by filling the contact hole 51 with a metal layer, and then planarizing the metal layer until a top surface of the interlayer insulating layer 60 is exposed.

Referring to FIG. 3R, a bit line 54 may be formed on the contact plug 52. The bit line 54 may include a metal having a superior conductivity such as tungsten, aluminum, copper, tantalum or titanium. The bit line 54 may be formed by a deposition process of depositing a metal layer and a photolithography process of patterning the metal layer. The deposition process of depositing the metal layer may include a sputtering process or a chemical vapor deposition process. The photolithography process may include a photo process of forming a photoresist pattern and an etching process of removing the metal layer using the photoresist pattern as an etching mask.

In a method of manufacturing a phase change memory device in accordance with some embodiments, when forming the blocking structure 40, a damage of the lower electrode 30 may be minimized because of the etch-stop layer 42 including a metal oxide having a high etching selectivity compared with a metal nitride layer of the lower electrode 30.

As described above, according to embodiments, a blocking structure including an etch-stop layer of a metal oxide having a high etching selectivity compared with a metal nitride layer of the lower electrode may be formed. Thus, when forming the blocking structure, damage to the lower electrode may be minimized.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

1. A phase change memory device comprising:
a mold oxide layer on a substrate;
a lower electrode on the mold oxide layer and connected to the substrate;
a blocking structure covering a part of the lower electrode and including an etch-stop layer and a blocking structure insulating layer; and
a phase change layer covering a remaining part of the lower electrode not covered by the blocking structure,
wherein the etch-stop layer includes a material having a higher etching selectivity than a material of the lower electrode.

2. The phase change memory device as claimed in claim 1, wherein the etch-stop layer includes a metal oxide.

3. The phase change memory device as claimed in claim 2, wherein the metal oxide includes an aluminum oxide.

4. The phase change memory device as claimed in claim 3, wherein the lower electrode includes a metal nitride layer.

5. The phase change memory device as claimed in claim 4, wherein the metal nitride layer includes a titanium nitride.

6-15. (canceled)

16. A phase change memory device comprising:
a mold oxide layer on a substrate;
a lower electrode in a gap of the mold oxide layer and connected to the substrate, an upper surface of the mold oxide layer being aligned with an upper surface of the lower electrode;
a phase change layer on the upper surface of the lower electrode and a portion of the upper surface of the mold oxide layer adjacent to the lower electrode;
a blocking structure between a portion of the phase change layer and a portion of the lower electrode, the blocking structure reducing a contact area between the phase change layer and the lower electrode, and the blocking structure including an etch-stop layer and a blocking structure insulating layer,
wherein the etch-stop layer includes a material having a higher etching selectivity than a material of the lower electrode.

17. The phase change memory device as claimed in claim 16, wherein the etch-stop layer includes a metal oxide and the lower electrode includes a metal nitride.
